(19) United States
(12) Patent Application Publication
(10) Pub. No.: US 2025/0207679 A1
(43) Pub. Date: Jun. 26, 2025

(54) GAS DELIVERY SYSTEM

(71) Applicant: Applied Materials, Inc., Santa Clara, CA (US)

(72) Inventors: Tom Cho, Los Altos, CA (US); Chien-Min Liao, San Jose, CA (US); Ming Xu, San Jose, CA (US); Gregory Phillip Lim, Fremont, CA (US); Hari K. Ponnekanti, San Jose, CA (US); Bruce Corvin Alger, San Jose, CA (US); Sungmin Cho, Menlo Park, CA (US); James Christopher Hansen, Mountain View, CA (US); Danny Cam Toan Lu, South San Francisco, CA (US); Mayra Ramirez, Gilroy, CA (US)

(21) Appl. No.: 18/984,643

(22) Filed: Dec. 17, 2024

Related U.S. Application Data
(60) Provisional application No. 63/614,375, filed on Dec. 22, 2023.

(51) Int. Cl. F16K 27/00

(52) U.S. Cl. CPC F16K 27/003

(57) ABSTRACT

A gas delivery system includes a substrate. The substrate includes a first substrate portion of a first gas stick. The first substrate portion includes a first inlet configured to receive a first gas. The first gas stick is to control first flow of the first gas. The substrate further includes a second substrate portion of a second gas stick. The second substrate portion includes a second inlet configured to receive a second gas. The second gas stick is to control second flow of the second gas separate from the first flow of the first gas. The gas delivery system is to provide the first gas and the second gas to a chamber of a substrate processing system.

### RELATED APPLICATION

This application claims benefit of U.S. Provisional App. No. 63/614,375, filed Dec. 22, 2023, the contents of which are incorporated herein in their entirety.

### TECHNICAL FIELD

Embodiments of the present disclosure relate to delivery systems, such as those used in association with substrate processing systems, and in particular to gas delivery systems.

### BACKGROUND

In substrate processing and other electronics processing, one or more types of gases are provided into chambers. The gases may be used for different operations.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, a gas delivery system includes a substrate. The substrate includes a first substrate portion of a first gas stick. The first substrate portion includes a first inlet configured to receive a first gas. The first gas stick is to control first flow of the first gas. The substrate further includes a second substrate portion of a second gas stick. The second substrate portion includes a second inlet configured to receive a second gas. The second gas stick is to control second flow of the second gas separate from the first flow of the first gas. The gas delivery system is to provide the first gas and the second gas to a chamber of a substrate processing system.

In another aspect of the disclosure, a gas delivery system includes a substrate. The substrate includes a first substrate portion of a first gas stick. The first substrate portion includes: a first inlet configured to receive a first gas; and a first base portion of a first component. The first base portion includes a first component inlet and a first component outlet. The gas delivery system further includes a first upper portion of the first component. The first upper portion is disposed on the first base portion. The first upper portion is configured to control first flow of the first gas to a chamber of a substrate processing system.

In another aspect of the disclosure, a gas delivery system includes an additively manufactured substrate. The additively manufactured substrate includes a first substrate portion of a first gas stick. The first substrate portion includes a first inlet configured to receive a first gas. The first substrate portion forms one or more first flow paths configured to route the first gas. The additively manufactured substrate further includes a second substrate portion of a second gas stick. The second substrate portion includes a second inlet configured to receive a second gas. The second substrate portion forms one or more second flow paths configured to route at least one of the first gas or the second gas to a chamber of a substrate processing system.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIGS. 1A-D illustrate components of gas delivery systems, according to certain embodiments.

FIG. 2 illustrates a substrate of a gas delivery system, according to certain embodiments.

FIG. 3 illustrates a substrate of a gas delivery system, according to certain embodiments.

FIGS. 4A-B illustrate substrates of gas delivery systems, according to certain embodiments.

### DETAILED DESCRIPTION OF EMBODIMENTS

Embodiments described herein are related to gas delivery systems (e.g., method of minimum pitch gas delivering system and component integration).

In substrate processing and other electronics processing, one or more types of gases are provided into chambers. The gases may be used for different operations. For example, gases are provided into processing chambers for substrate processing operations. In some examples, gas (e.g., inert gas, nitrogen, etc.) is provided into the factory interface and/or load lock to reduce oxidation of substrates. Gas can be provided for purging of a vacuum pump. Fluids (e.g., gas, liquid, etc.) may be provided into processing chambers for cleaning operations.

In conventional systems, different gas delivery components receive different gases. The different gas delivery components are removably coupled together. Different flow paths are created by coupling piping to different parts of the gas delivery components. In the conventional systems, the removably attached gas delivery components take up a large amount of space which may increase the overall footprint of the substrate processing system and may limit other components that can be installed in the substrate processing system. In conventional systems, the removably attached gas delivery components that include piping coupling different parts of the gas delivery components may be subject to wearing down of parts, increased maintenance, increased replacement of parts, and leaking. The conventional systems have increased downtime, have decreased yield, increase substrate irregularities, and decrease substrate quality.

The components, assemblies, systems, and methods disclosed herein provide solutions to these and other problems of conventional systems.

The present disclosure includes a gas delivery system that includes two or more gas sticks. A gas stick may refer to a manifold that has components (e.g., devices) that are mounted on an exterior surface (e.g., upper surface) of the manifold. The manifold forms fluid flow channels that can be connected to the different components. The components can include one or more of check valve, filter, nozzle, regulator, shut-off valve, pneumatic valve, check valve, mass flow controller (MFC), and/or manual valve. A first gas stick is a first manifold (e.g., has a first inlet and a second gas stick is a second manifold (e.g., has a second inlet). The first gas stick and the second gas stick have corresponding components (e.g., valve, filter, MFC, etc.) coupled to the corresponding manifold. The first gas stick and the second gas stick may be routed next to each other so that the first inlet and the second inlet are at a first distal end and the first gas stick and the second gas stick extend towards a second distal end.

The gas delivery system includes a substrate that includes a first substrate portion of the first gas stick and a second substrate portion of the second gas stick. The first substrate portion and the second substrate portion may be an integral component (e.g., that is printed via additive manufacturing).

The first substrate portion includes a first inlet configured to receive a first gas. The first gas stick is to control first flow of the first gas (e.g., via one or more first components of the first gas stick).

The second substrate portion includes a second inlet configured to receive a second gas. In some embodiments, the second gas stick is to control second flow of the second gas separate from the first flow of the first gas. The gas delivery system is to provide the first gas and the second gas to a chamber (e.g., a processing chamber, a factory interface, and/or a load lock) of a substrate processing system.

The components, systems, and methods disclosed herein have advantages over conventional solutions. The gas delivery system of the present disclosure may have a common substrate for the different gas sticks. This may cause the gas delivery system of the present disclosure to be smaller (e.g., in an x-direction, in a y-direction, and/or in a z-direction) than a conventional system. This may allow the present disclosure to have a smaller footprint and allow for more components to be installed in a substrate processing system compared to conventional systems. Having a common substrate for the different gas sticks also allows the gas delivery system of the present disclosure to have less parts than a conventional system. This allows the present disclosure to have less wearing down of parts, decreased maintenance, decreased replacement of parts, and decreased leaking compared to conventional systems. The present disclosure may also have decreased downtime, have increased yield, decreased substrate irregularities, and increased substrate quality compared to conventional systems.

Although some embodiments of the present disclosure are described with relation to gas delivery systems, in some embodiments, the present disclosure may be used for fluid distribution systems (e.g., provide one or more gases and/or one or more liquids).

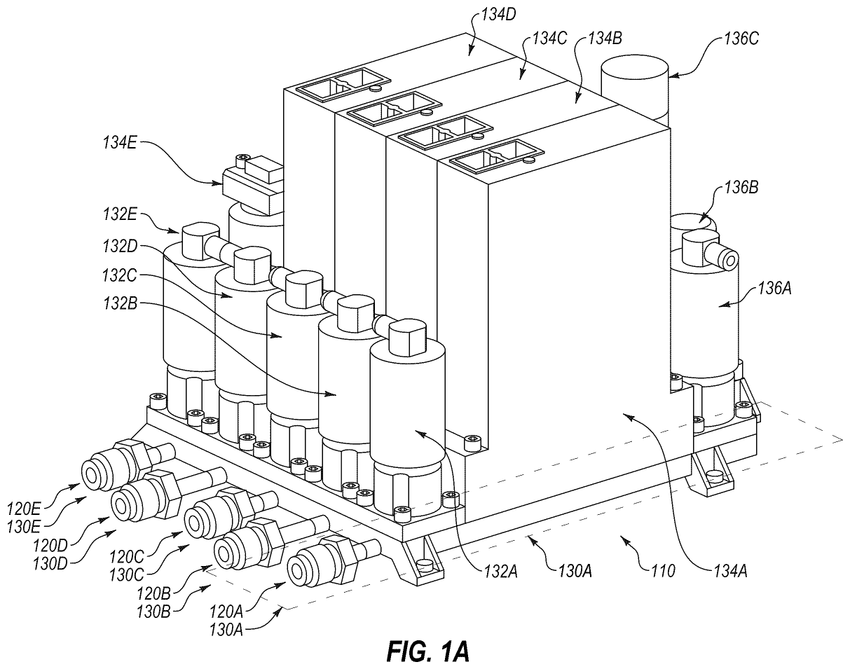

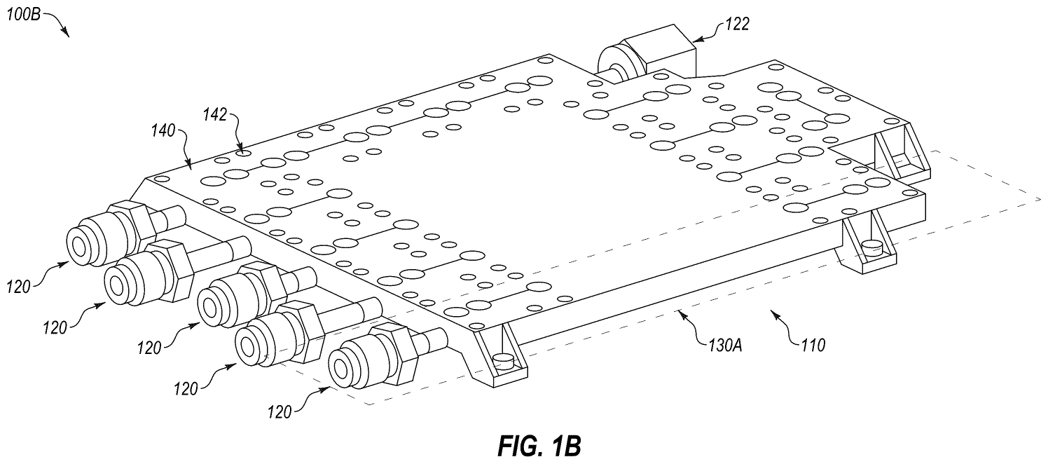

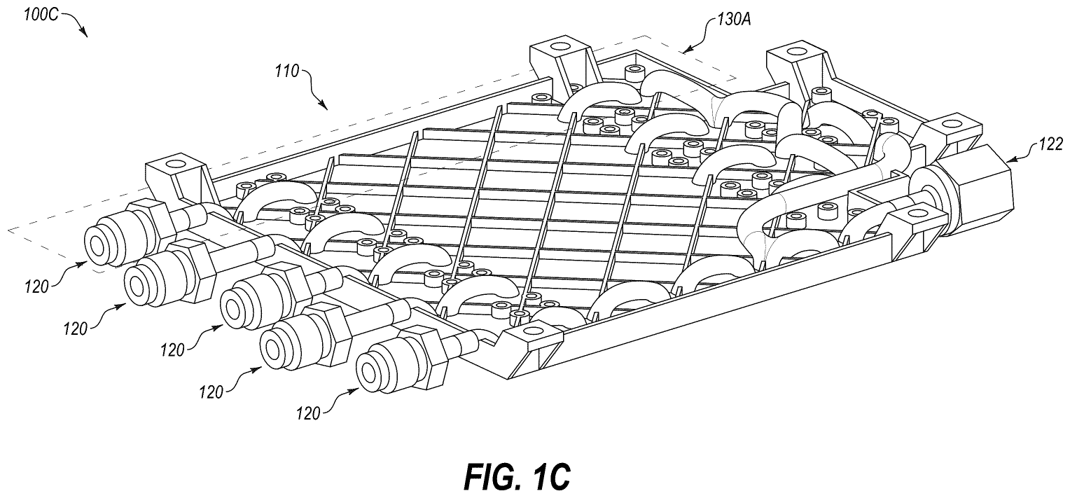

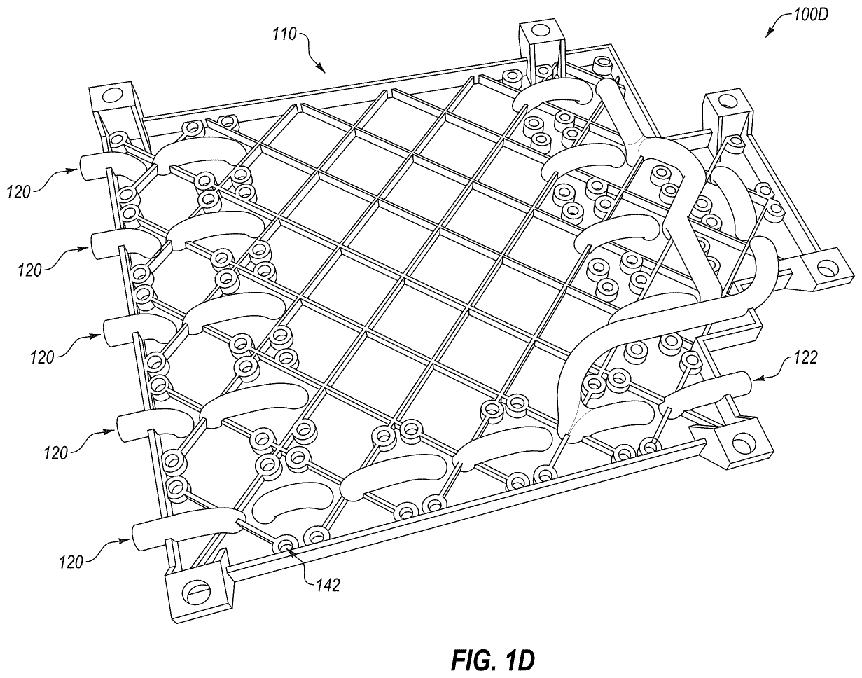

FIGS. 1A-D illustrate components of gas delivery systems 100, according to certain embodiments. FIG. 1A illustrates a top perspective view of a gas delivery system 100 including a substrate 110, inlets 120, and components 132-136. FIG. 1B illustrates a top perspective view of a substrate 110, inlets 120, and outlet 122. FIGS. 1C-D illustrate bottom perspective views of substrates 110, inlets 120, and outlets 122. Two or more of FIGS. 1A-D may be of components of the same gas delivery system 100.

A gas delivery system 100 may include two or more gas sticks 130. A gas stick 130 refers to a manifold that forms different gas channels (e.g., pathways). A gas stick 130 has different components 132-136 mounted on (e.g., a top surface of) a portion of substrate 110.

A gas delivery system 100 may have gas sticks 130A-E, where each gas stick 130 has a corresponding inlet 120. For example, gas stick 130A has an inlet 120A, gas stick 130B has an inlet 120B, gas stick 130C has an inlet 120C, gas stick 130D has an inlet 120D, and gas stick 130E has an inlet 120E. Each gas stick 130 has components (e.g., devices), such as components 132-136. For example, gas stick 130A has components 132A-136A, gas stick 130B has components 132B-136B, gas stick 130C has components 132C-136C, gas stick 130D has components 132D-136D, and gas stick 130E has components 132E-136E. Components 132-136 may be one or more of check valve, filter, nozzle, regulator, shut-off valve, pneumatic valve, check valve, MFC, and/or manual valve. A gas stick 130 may have one or more components, two or more components, three or more components, etc. The different gas sticks 130 may have the same amount of components or different amounts of components.

One or more of the gas sticks 130 may have an outlet 122. In some embodiments, each gas stick has a corresponding outlet 122. In some embodiments, the gas delivery system 100 has less outlets 122 than gas sticks 130. In some embodiments, the gas delivery system 100 has multiple inlets 120 and one outlet 122.

The substrate 110 has inlets 120 and one or more outlets 122. The substrate forms flow path openings 140, mounting openings 142, and flow channels (e.g., within the substrate 11). Each flow channel is fluidly coupled to one or more inlets 120, one or more flow path openings 140 formed by the substrate 110, one or more other flow channels, and/or one or more outlets 122. Components 132-136 are coupled to one or more flow path openings 140 (e.g., at least two flow path openings 140, one being an inlet and one being an outlet) formed by the substrate 110. Components 132-136 are mounted to the substrate 110 via fasteners and the mounting openings 142.

Conventional gas sticks are removably attached to each other (e.g., via fasteners) and have piping that are routed above and below the gas sticks to attach the different flow path openings to each other. As such, conventional gas sticks take up more room, require more maintenance, have more parts, and have more leaking than the gas delivery systems (e.g., gas delivery system 100) of the present disclosure.

Each gas stick 130 has a corresponding substrate portion of substrate 110. In some embodiments, the different portions of substrate 110 are additively manufactured (e.g., three-dimensionally (3D) printed) as an integral substrate. In some embodiments, the different portions of substrate 110 are created via one or more of additive manufacturing, welding, bonding, joined, casted, etc. (e.g., into an integral substrate 110).

The different substrate portions of the substrate 110 form integral flow paths between the substrate portions. In some embodiments, a first flow path of the integral flow paths is disposed above a second flow path of the integral flow paths (e.g., overlapping flow paths are disposed in the substrate 110).

In some embodiments, the gas delivery system 100 includes components that include one or more of a check valve, filter, nozzle, regulator, shut-off valve, pneumatic valve, check valve, MFC, and/or manual valve. One or more of the plurality of components are mounted on one or more of the substrate portions of the substrate 110.

In some embodiments, a base portion of at least one of the components is integral to a corresponding substrate portion of the substrate 110. The base portion includes a component inlet and a component outlet.

In some embodiments, the gas delivery system 100 (e.g., substrate 110) further includes a first outlet 122 of the first substrate portion of a first gas stick 130 (e.g., the first outlet configured to provide the first gas to a chamber of a substrate processing system) and a second outlet 122 of the second substrate portion of a second gas stick 130 (e.g., the second outlet configured to provide the second gas to the chamber of the substrate processing system).

In some embodiments, an upper surface of the substrate 110 is substantially planar (e.g., see FIG. 1B) and components are to be mounted on the upper surface of the substrate 110. In some embodiments, the substrate 110 (e.g., see FIG. 1C and/or FIG. 1D) includes webbing (e.g., to provide strength) on a lower surface and/or additively manufactured conduits that at least partially protrude from the lower surface (e.g., the additively manufactured conduits are integral to the substrate 110).

In some embodiments, gas delivery system 100 is used for a method of minimum pitch gas delivering with component integration. The gas delivery system 100 may use design and manufacturing technique to integrate gas sticks 130 (e.g., single gas sticks 130) of a chamber to a whole gas delivering unit as a gas pallet or gas panel in a minimum form (e.g., smaller than conventional systems). In some embodiments, by integration of redundant functions and components, in one or more directions (e.g., X-Y-Z three directions), the size of the gas delivering system 100 is minimized (e.g., smaller than conventional systems). Integrated gas delivering system 100 may also consolidate the components (e.g., components 132-136) per function to enhance manufacturability, reduce the time on assembling, and lower cost.

In some embodiments, performance enhanced and cost-effective gas delivering system 100 may be provided by integrating a group of gas sticks 130 as a whole pallet or panel. By reducing the form size and consolidating the similar function, lower cost of material usage, manufacturing operations, and delivery may be achieved.

The present disclosure may integrate single gas sticks used in chamber gas delivering systems as a whole substrate 110 to: 1) reduce the size and form to minimal shape; 2) consolidate the redundant functions; 3) enhance the flexibility of routing between functional modules; and/or 4) reduce the cost of assembling, testing, and delivering.

The present disclosure may: reduce the size of the form to minimal shape to save fab space; consolidate redundant functions; enhance flexibility of routing between functional modules, reduce cost of assembling, testing, and/or delivering; reduce consumption of materials; and/or shorten the gas delivering path for better chamber control and/or reaction.

In some embodiments, the present disclosure integrates gas sticks 130 (e.g., sorts the gas stick 130 per function and correlation, integrate individual gas sticks 130 as a pallet or whole panel to eliminate the redundant function and to enhance form size control).

In some embodiments, the present disclosure has flexible routing between functions (e.g., uses additive manufacturing in generating gas paths for enhancing manufacturability of flexible routing).

In some embodiments, the present disclosure shortens one or more gas paths to enhance response control time in gas delivering.

In some embodiments, the present disclosure integrates component substrate (e.g., combine block and base mount to reduce height; adjusting length, dimension, and correlation of gas path to enhance the component function).

In some embodiments, the present disclosure provides an integrated gas panel, a minimum gas panel form, and/or flexible gas path routing.

In some embodiments, the present disclosure minimizes a gas delivery system 100 size by integrating individual gas sticks 130 as a gas pallet or panel and by re-arranging components (e.g., components 132-136) for consolidation. In some embodiments, the present disclosure integrates functions by additive manufacturing of the substrate 110.

Conventional systems include piping, seals, weldments, etc. In some embodiments, the present disclosure has less piping, seals, weldments, etc. compared to conventional systems.

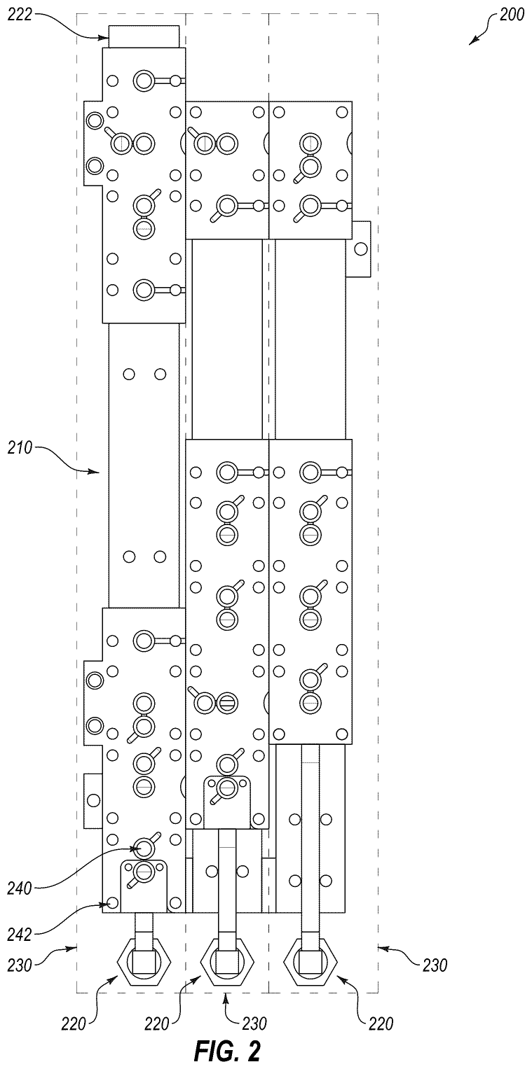

FIG. 2 illustrates a substrate 210 (e.g., substrate 110 of one or more of FIGS. 1A-D) of a gas delivery system 200 (e.g., gas delivery system 100 of one or more of FIGS. 1A-D), according to certain embodiments.

Substrate 210 has different substrate portions that are integral to each other and correspond to different gas sticks 230 (e.g., gas sticks 130 of one or more of FIGS. 1A-D). Each substrate portion of substrate 210 is a manifold that forms flow paths, has flow path openings 240 (e.g., flow path openings 140 of one or more of FIGS. 1A-D), and mounting openings 242 (e.g., mounting openings 142 of one or more of FIGS. 1A-D).

Conventional gas sticks are removably attached to each other which takes up more space in at least one direction (e.g., x-direction left to right of FIG. 2). In some embodiments of the present disclosure, the substrate 210 is an integral component (e.g., common substrate) that is used by all gas sticks 230. This allows substrate 210 and gas delivery system 200 to take up less space in at least one direction (e.g., x-direction, left to right of FIG. 2) compared to conventional systems.

In some embodiments, the size of the gas delivery system 200 (e.g., substrate 210) is reduced in at least one direction (e.g., along the x-axis) by removing the mounting place (e.g., portions of substrate 210 are integral to each other instead of being fastened to each other) and/or reducing gas channels (e.g., flow channels) in the at least one direction (e.g., reducing gas channels along the x-axis).

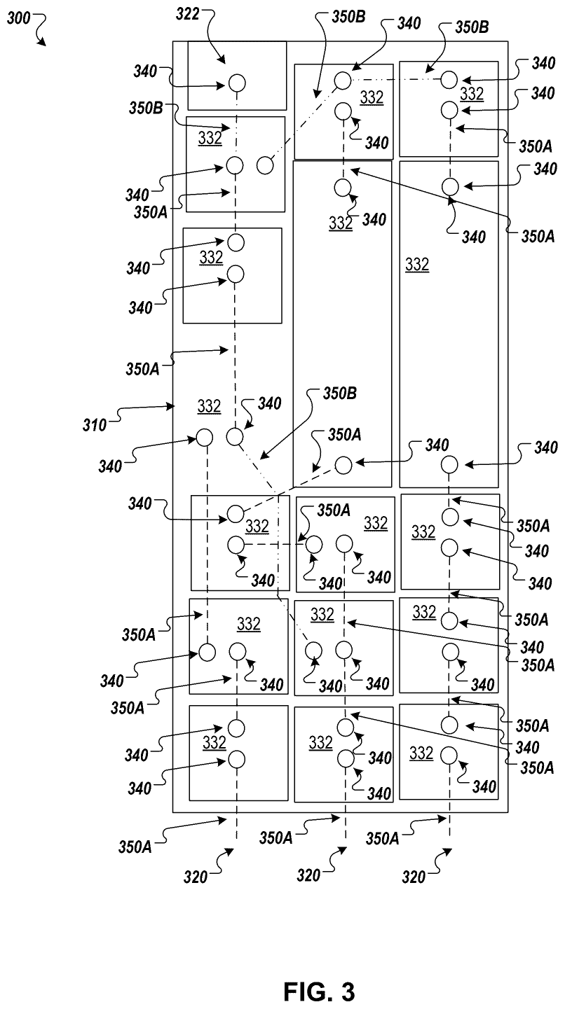

FIG. 3 illustrates a substrate 310 (e.g., substrate 110 of one or more of FIGS. 1A-D, substrate 210 of FIG. 2) of a gas delivery system 300 (e.g., gas delivery system 100 of one or more of FIGS. 1A-D, gas delivery system 200 of FIG. 2), according to certain embodiments.

Substrate 310 has different substrate portions that are integral to each other and correspond to different gas sticks 330 (e.g., gas sticks 130 of one or more of FIGS. 1A-D, gas sticks 230 of FIG. 2). Each substrate portion of substrate 310 is a manifold that forms flow paths, has flow path openings 340 (e.g., flow path openings 140 of one or more of FIGS. 1A-D, flow path openings 240 of FIG. 2), and mounting openings 342 (e.g., mounting openings 142 of one or more of FIGS. 1A-D, mounting openings 242 of FIG. 2).

Conventional gas sticks have piping that is routed above and below the gas sticks to couple the different manifolds and components to each other. This causes the components to be spread out which takes up more space in at least one direction (e.g., y-direction up and down on FIG. 2). In some embodiments of the present disclosure, the substrate 310 is an integral component (e.g., common substrate) that is used by all gas sticks 230, where the substrate 310 forms integral flow paths within the substrate 310. This allows consolidated configurations of components on the substrate 310 (e.g., without spreading out the layout of the components to allow for different piping above and below the gas sticks) which allows the substrate 310 and gas delivery system 300 to take up less space in at least one direction (e.g., y-direction, up and down in FIG. 2) compared to conventional systems.

In some embodiments, substrate 310 forms flow paths 350 (e.g., within the substrate 310), flow path openings 340 (e.g., flow path openings 140 of one or more of FIGS. 1A-D, flow path openings 240 of FIG. 2, etc.). In some embodiments, one or more flow paths 350A are at least partially in a first plane and one or more flow paths 350B are at least partially in a second plane (e.g., flow paths 350A and 350B overlap each other).

The flow path openings 340 may connect the flow paths 350 to a component 332. Each component 332 may fluidly couple to two flow path openings 340. The components 332 may include one or more of a manual valve, a pneumatic valve, a filter, a control valve, an MFC, etc. In some embodiments, one or more of the components 332 may be controlled (e.g., via a controller) to adjust flow through one or more of the flow paths 350. For example, flow can be shut off via one or more first components 332 and allowed via one or more second components.

In some embodiments, the size of the gas delivery system 300 (e.g., substrate 310) is reduced in at least one direction (e.g., along the y-axis) by arranging the components 432 (e.g., valve, filter, etc.) per function to minimize the size in the at least one direction (e.g., in the y-direction). Flexible routing (e.g., additively manufacturing the substrate 310 specific for the use of the gas delivery system 300) may allow different types of routing (e.g., x-routing, y-routing, tilt-routing, x-y diagonal gas line routing, tilted-angle gas line routing) between the components 332.

In some embodiments, the gas delivery system 300 includes a substrate 310 that is an additively manufactured substrate and includes a first substrate portion of a first gas stick (e.g., gas stick 130A of FIGS. 1A-D) and a second substrate portion of a second gas stick (e.g., gas stick 130B of FIGS. 1A-D). The first substrate portion may include a first inlet 320 configured to receive a first gas (e.g., nitrogen (N₂), nitrogen trifluoride (NF₃), argon (Ar), etc.). The first substrate portion may form one or more first flow paths configured to route the first gas. The second substrate portion may include a second inlet 320 configured to receive a second gas (e.g., N₂, NF₃, Ar, etc.). The second gas may be different from the first gas (e.g., the first gas is N₂ and the second gas is NF₃). The second substrate portion forms one or more second flow paths configured to route at least one of the first gas and/or the second gas to a chamber (e.g., a processing chamber, a factory interface, or a load lock) of a substrate processing system.

In some embodiments, the first substrate portion and the second substrate portion form integral flow paths between the first substrate portion and the second substrate portion. A first flow path of the plurality of integral flow paths may be disposed above a second flow path of the plurality of integral flow paths.

In some embodiments, the gas delivery system 300 includes components 332 that include one or more of a check valve, filter, nozzle, regulator, shut-off valve, pneumatic valve, check valve, mass flow controller, or manual valve. One or more of the components 332 are mounted on the first substrate portion. In some embodiments, a base portion of at least one of the components 332 is integral to the first substrate portion. The base portion may include a component inlet and a component outlet.

The gas delivery system may include an outlet 322 of the first substrate portion of the first gas stick. The outlet 322 may be configured to provide one or more gases to a chamber.

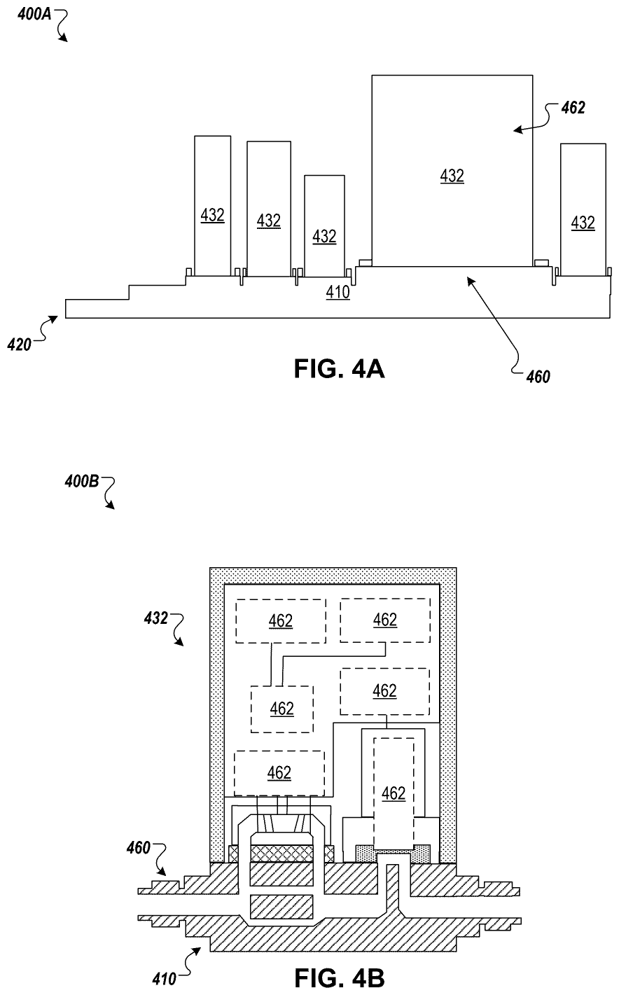

FIGS. 4A-B illustrate substrates 410 (e.g., substrate 110 of one or more of FIGS. 1A-D, substrate 210 of FIG. 2, substrate 310 of FIG. 3) of gas delivery systems 400 (e.g., gas delivery system 100 of one or more of FIGS. 1A-D, gas delivery system 200 of FIG. 2, gas delivery system 300 of FIG. 3), according to certain embodiments. Substrate 410 may have an inlet 420 (e.g., inlet 120 of one or more of FIGS. 1A-D, inlet 220 of FIG. 2, inlet 320 of FIG. 3).

Gas delivery system 400 has components 432 (e.g., components 132-136 of one or more of FIGS. 1A-D, components 332 of FIG. 3). In some embodiments, a portion of a component 432 is integral to substrate 410 and a portion of the component is disposed on the substrate. The mechanical portions of the component 432 (e.g., component fluid inlet, component fluid outlet, component flow paths, etc.) may be integral to the substrate 410 and the controls (e.g., driver, receiver, converter, processing device, valve driver circuit, etc.) of the component 432 may be disposed on the substrate 410.

Conventionally, an entire component is disposed on a manifold which causes conventional gas delivery systems to take up more space in at least one direction (e.g., z-direction, up and down in one or more of FIGS. 4A-B). In some embodiments of the present disclosure, a base portion 460 of component 432 is integral to the substrate 410 (e.g., substrate is additively manufactured to include base portion 460. The base portion 460 includes the component inlet and the component outlet. The controls 462 of the component 432 are disposed on the substrate 410 (e.g., on the base portion 460). This allows the gas delivery system 400 to take up less space in at least one direction (e.g., z-direction, up and down in one or more of FIGS. 4A-B) compared to conventional systems.

In some embodiments, the gas delivery system 400 may provide function integration to minimize size in at least one direction (e.g., along the z-axis). This may reduce the size in at least one direction (e.g., along z-axis) by one or more of: integrating the component baseplate (e.g., base portion 460 of component 432) into the substrate 410; and/or enhancing the function (e.g., sensor sensitivity) of the component 432 (e.g., elongate the gas path for flow rate sensing by using topology, optimizing design and manufacturing method, such as by 3D printing, etc.).

In some embodiments, gas delivery system 400 includes a substrate 410 that includes a first substrate portion of a first gas stick and a second substrate portion of a second gas stick. The first substrate portion may include a first inlet 420 configured to receive a first gas and a first base portion 460 of a first component 432. The first base portion 460 may include a first component inlet and a first component outlet. The gas delivery system 400 may further include a first upper portion (e.g., controls 462) of the first component 432. The first upper portion may be disposed on the first base portion 460. The first upper portion may be configured to control first flow of the first gas to a chamber of a substrate processing system.

In some embodiments, the substrate 410 includes a second substrate portion of a second gas stick, the second substrate portion including a second inlet configured to receive a second gas and a second base portion (e.g., including a second component inlet and a second component outlet) of a second component. The gas delivery system 400 may include a second upper portion (e.g., controls 462) of the second component. The second upper portion being disposed on the second base portion 460. The second upper portion is configured to control second flow of the second gas.

The first substrate portion and the second substrate portion may be additively manufactured as an integral substrate. The first substrate portion and the second substrate portion may form integral flow paths between the first substrate portion and the second substrate portion. A first flow path of the integral flow paths is disposed above a second flow path of the integral flow paths.

In some embodiments, the component 432 includes one or more of a check valve, filter, nozzle, regulator, shut-off valve, pneumatic valve, check valve, mass flow controller, or manual valve. In some embodiments, the chamber is a processing chamber, a factory interface, or a load lock.

In some embodiments, one or more features of one or more FIGS. 1A-4B may be combined together in a gas delivery system and/or a substrate (e.g., additive pallet) of the gas delivery system. This may reduce the component usage (e.g., less seals, piping, weldments, fasteners, etc.), simplify the assembly procedure, reduce leak rate (e.g., since less joints), and/or reduce the size with being flexible on arranging the components.

Unless specifically stated otherwise, terms such as “causing,” determining,” “flowing,” “receiving,” “transmitting,” “generating,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein, or it includes a general purpose computer system selectively programmed by a computer program stored in the computer system. In some embodiments, such a computer program is stored in a computer-readable tangible storage medium.

The methods and illustrative examples described herein are not inherently related to any particular computer or other apparatus. Various general purpose systems can be used in accordance with the teachings described herein, or a more specialized apparatus can be constructed to perform methods described herein and/or each of their individual functions, routines, subroutines, or operations. Examples of the structure for a variety of these systems are set forth in the description above.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure can practiced without these specific details. In other instances, well-known components or methods are not described in detail or are presented in simple block diagram format in order to avoid unnecessarily obscuring the present disclosure. Thus, the specific details set forth are merely exemplary. Particular implementations can vary from these exemplary details and still be contemplated to be within the scope of the present disclosure.

The terms “over,” “under,” “between,” “disposed on,” “support,” and “on” as used herein refer to a relative position of one material layer or component with respect to other layers or components. For example, one layer disposed on, over, or under another layer may be directly in contact with the other layer or may have one or more intervening layers. Moreover, one layer disposed between two layers may be directly in contact with the two layers or may have one or more intervening layers. Similarly, unless explicitly stated otherwise, one feature disposed between two features may be in direct contact with the adjacent features or may have one or more intervening layers.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method can be altered so that certain operations are performed in an inverse order so that certain operations are performed, at least in part, concurrently with other operations. In another embodiment, instructions or sub-operations of distinct operations are in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A gas delivery system comprising:
a substrate comprising:
a first substrate portion of a first gas stick, the first substrate portion comprising a first inlet configured to receive a first gas, wherein the first gas stick is to control first flow of the first gas; and
a second substrate portion of a second gas stick, the second substrate portion comprising a second inlet configured to receive a second gas, wherein the second gas stick is to control second flow of the second gas separate from the first flow of the first gas, and wherein the gas delivery system is to provide the first gas and the second gas to a chamber of a substrate processing system.

2. The gas delivery system of claim 1, wherein the chamber is a processing chamber, a factory interface, or a load lock.

3. The gas delivery system of claim 1, wherein the first substrate portion and the second substrate portion are additively manufactured as an integral substrate.

4. The gas delivery system of claim 1, wherein the first substrate portion and the second substrate portion form a plurality of integral flow paths between the first substrate portion and the second substrate portion.

5. The gas delivery system of claim 4, wherein a first flow path of the plurality of integral flow paths is disposed above a second flow path of the plurality of integral flow paths.

6. The gas delivery system of claim 1 further comprising a plurality of components comprising one or more of a check valve, filter, nozzle, regulator, shut-off valve, pneumatic valve, check valve, mass flow controller, or manual valve, wherein one or more of the plurality of components are mounted on the first substrate portion.

7. The gas delivery system of claim 6, wherein a base portion of at least one of the plurality of components is integral to the first substrate portion, wherein the base portion comprises a component inlet and a component outlet.

8. The gas delivery system of claim 1 further comprising:
a first outlet of the first substrate portion of the first gas stick, the first outlet configured to provide the first gas to the chamber of the substrate processing system.

9. A gas delivery system comprising:
a substrate comprising:
a first substrate portion of a first gas stick, the first substrate portion comprising:
a first inlet configured to receive a first gas; and
a first base portion of a first component, the first base portion comprising a first component inlet and a first component outlet; and
a first upper portion of the first component, the first upper portion being disposed on the first base portion, wherein the first upper portion is configured to control first flow of the first gas to a chamber of a substrate processing system.

10. The gas delivery system of claim 9, wherein the substrate further comprises:
a second substrate portion of a second gas stick, the second substrate portion comprising:
a second inlet configured to receive a second gas; and
a second base portion of a second component, the second base portion comprising a second component inlet and a second component outlet, wherein the gas delivery system further comprises a second upper portion of the second component, the second upper portion being disposed on the second base portion, wherein the second upper portion is configured to control second flow of the second gas.

11. The gas delivery system of claim 10, wherein the first substrate portion and the second substrate portion are additively manufactured as an integral substrate.

12. The gas delivery system of claim 10, wherein the first substrate portion and the second substrate portion form a plurality of integral flow paths between the first substrate portion and the second substrate portion, and wherein a first flow path of the plurality of integral flow paths is disposed above a second flow path of the plurality of integral flow paths.

13. The gas delivery system of claim 9, wherein the first component comprises one or more of a check valve, filter, nozzle, regulator, shut-off valve, pneumatic valve, check valve, mass flow controller, or manual valve.

14. The gas delivery system of claim 9, wherein the chamber is a processing chamber, a factory interface, or a load lock.

15. A gas delivery system comprising:
an additively manufactured substrate comprising:
a first substrate portion of a first gas stick, the first substrate portion comprising a first inlet configured to receive a first gas, the first substrate portion forming one or more first flow paths configured to route the first gas; and
a second substrate portion of a second gas stick, the second substrate portion comprising a second inlet configured to receive a second gas, the second substrate portion forming one or more second flow paths configured to route at least one of the first gas or the second gas to a chamber of a substrate processing system.

16. The gas delivery system of claim 15, wherein the chamber is a processing chamber, a factory interface, or a load lock.

17. The gas delivery system of claim 15, wherein the first substrate portion and the second substrate portion form a plurality of integral flow paths between the first substrate portion and the second substrate portion, and wherein a first flow path of the plurality of integral flow paths is disposed above a second flow path of the plurality of integral flow paths.

18. The gas delivery system of claim 15 further comprising a plurality of components comprising one or more of a check valve, filter, nozzle, regulator, shut-off valve, pneumatic valve, check valve, mass flow controller, or manual valve, wherein one or more of the plurality of components are mounted on the first substrate portion.

19. The gas delivery system of claim 18, wherein a base portion of at least one of the plurality of components is integral to the first substrate portion, wherein the base portion comprises a component inlet and a component outlet.

20. The gas delivery system of claim 15 further comprising:
a first outlet of the first substrate portion of the first gas stick, the first outlet configured to provide the first gas to the chamber.
